(19) United States
(12) Patent Application Publication
(10) Pub. No.: US 2024/0213394 A1
(43) Pub. Date: Jun. 27, 2024

(54) METHOD FOR LAMINATING SOLAR CELLS

(71) Applicant: LIGHTYEAR LAYER IPCO B.V., Helmond (NL)

(72) Inventors: Emanuele CORNAGLIOTTI, Uccle (BE); Simone REGONDI, Eindhoven (NL); Dario DI CARLO RASI, Helmond (NL)

(21) Appl. No.: 18/555,833

(22) PCT Filed: Apr. 14, 2022
(86) PCT No.: PCT/EP2022/060109

§ 371 Date: Oct. 17, 2023

(30) Foreign Application Priority Data
Apr. 18, 2021 (NL) 2028006

(51) Int. Cl. H01L 31/18; H01L 31/048; H01L 31/05

(52) U.S. Cl. CPC H01L 31/18; H01L 31/0481; H01L 31/0516

(57) ABSTRACT

The invention pertains to a method for laminating solar cells, comprising: attaching a first side encapsulant (114) to solar cells, which first side encapsulant is made of a first encapsulant material, the first side encapsulant being attached to one of the photosensitive side and the backside of the solar cells forming at least a part of a stack by, after attaching the first side encapsulant to the solar cells, attaching a second side encapsulant (112) to the other one of the photosensitive side and the backside of the solar cells, the second side encapsulant (114) being made of a second encapsulant material which is different from the first encapsulant material, and wherein the first encapsulant material has a change of dimensions which is less than the change of dimensions of the second encapsulant material.

### TECHNICAL FIELD OF THE INVENTION

The invention relates to a method for laminating solar cells, for example using a laminator.

The laminator for example has an evacuable volume for placing a workpiece therein, the volume comprising a heatable plate for heating the workpiece, the volume showing a membrane for pressing against the workpiece when the volume is evacuated, the solar cells having a photosensitive frontside sensitive to light and a backside, the method comprising attaching a backside encapsulant (BSE) to the backside of the solar cells and attaching a frontside encapsulant (FSE) to the frontside of the solar cells, the frontside encapsulant (FSE) showing a high transmissivity for light, the encapsulants and the solar cells forming at least part of a stack.

### BACKGROUND OF THE INVENTION

Laminating solar cells is well-known in the solar industry. The solar cells are sealed from the environment, thereby increasing their lifetime.

Such a method of laminating is known from, for example, US patent application publication US20140130848A1. Typically the solar cells are encapsulated between two sheets of, for example, EVA (Ethylene Vinyl Acetate) in a laminator. EVA is an often used encapsulant as it is cheap and highly transparent. The resultant laminate of EVA/solar cells/EVA may then be adhered to a transparent cover, for example a glass or polycarbonate cover.

It is noted that the transparent cover can be a flat cover, as often used in housing, or it can be a 3D curved cover. Measures can be taken to make the aforementioned sheet flexible when the cover is curved.

It is further noted that a laminator for laminating solar cells is an apparatus known as such, see for example JP2010023485A to Kyocera or the SPL2860 PIN Solar Panel Laminator sold by Bent River Machine Inc., Clarkdale, Arizona, USA.

A problem that arises when laminating solar cells is that, as long as the EVA is not cured, the position of the cells on the still uncured EVA is not stable: the cells can ‘float’ over the surface of the sheets of encapsulant. This problem occurs especially when the sheets of EVA and the cells are pressed together in a laminator, and the EVA is heated. The EVA then becomes soft while a membrane presses on the uppermost layer of encapsulant.

Another problem is that an encapsulant such as EVA shows a “change of dimensions”: a change of dimensions by heating uncured encapsulant from room temperature to its curing temperature, and includes thermal expansion, shrinkage due to cross-linking, dimensional change due to relaxation of strain, etc. So, the “change of dimensions” is a property of the material that is used as encapsulant.

It is noted that, if the cells are electrically interconnected by so-called tabbing, using wires before encapsulation, the position of the cells is already well defined before encapsulation. However, if the cells are interconnected using a back-contact foil (BCF), and the interconnection between cells and back-contact foil (BCF) is typically made at the same time or after curing the encapsulants, the position of the cell is not yet defined at the moment of curing.

This problem is addressed in US patent application publication US2015249175A1. Here a layer of encapsulant showing an alignment portion is placed on a transparent top cover, such as glass. Solar cells are placed on the alignment portion, a second sheet of encapsulant is placed on the solar cells and the encapsulants are cured and thereby bonded to the solar cells. The alignment portion can be a sticky or tacky portion, in which case it is often referred to as pre-tagging.

The invention intends to offer an alternative way to laminate solar cells without, or at least with a much reduced displacement (movement) of the solar cells during the process of lamination.

### SUMMARY OF THE INVENTION

The method according to the invention comprises the following steps:
attaching a first side encapsulant (114) to solar cells, which first side encapsulant is made of a first encapsulant material, the solar cells (104) having a photosensitive frontside (106) sensitive to light and a backside (108), and the first side encapsulant being attached to one of the photosensitive side and the backside of the solar cells
forming at least a part of a stack by, after attaching the first side encapsulant to the solar cells, attaching a second side encapsulant (112) to the other one of the photosensitive side and the backside of the solar cells, the second side encapsulant (114) being made of a second encapsulant material which is different from the first encapsulant material, and wherein the first encapsulant material has a change of dimensions which is less than the change of dimensions of the second encapsulant material.

For example, the first side encapsulant is a backside encapsulant, and the second side encapsulant is a frontside encapsulant having a transmissivity for light. In that case, in the step of the attaching the solar cells to the first side encapsulant, the backside of the solar cells is attached to the backside encapsulant, and in the step of forming at least a part of a stack, the frontside encapsulant is attached to the photosensitive side of the solar cells.

Optionally, in the method according to the invention, a laminator is used which has an evacuable volume for placing a workpiece therein, the volume comprising a heatable plate for heating the workpiece, the volume showing a membrane for pressing against the workpiece when the volume is evacuated.

So, in the method according to the invention, the first side encapsulant, which is for example the backside encapsulant (BSE), shows a change of dimensions less than the change of dimensions of the second side encapsulant, which is e.g. the frontside encapsulant (FSE), and the solar cells are attached to the first side encapsulant (e.g. the backside encapsulant (BSE)) before the solar cells are attached to the second side encapsulant (e.g. the frontside encapsulant (FSE)). As a result of this, drifting of the solar cells before being attached to the second side encapsulant (e.g. the frontside encapsulant (FSE)) is decreased.

“Change of dimensions” is in the context of this invention the change of dimensions by heating uncured encapsulant from room temperature to its curing temperature, and includes the effects of thermal expansion, shrinkage due to cross-linking, dimensional change due to relaxation of strain, etc. Different materials have a different “change of dimensions”. So, in accordance with the invention, the second side encapsulant (e.g. frontside encapsulant) and the first side encapsulant (e.g. backside encapsulant) are made from different materials.

The invention is based on the insight that the change of dimensions of an often used front side encapsulant, EVA (Ethylene Vinyl Acetate) is approximately 4%, while that of, for example, an EPE (Encapsulant/Polyester/Encapsulant) sheet it is less than 0.5%. By first adhering the solar cells to an encapsulant that shows a lower change of dimensions the position of the cells is fixed with a high accuracy to the backside encapsulant (BSE), after which the cells are adhered to the transparent frontside encapsulant (FSE) (such as EVA).

It is noted that EPE can not be used on the photosensitive side of the solar cells, as the polymer film is (much) less transparent than the frontside encapsulant (FSE), typically EVA.

It is noted that Chinese Utility Model CN202758916U also discloses the use of a sheet of EPE in a solar panel. However, the solar cells are encapsulated in two layers of EVA, and the EPE is used to electrically insulate the solar cells from busbars and positioned on the backside encapsulant (BSE) layer, removed from the solar cells. This utility model does not mention the need or advantage of a low change of dimensions during curing.

It is further noted that US patent application publication US2018006178A1 also discloses solar cells that are laminated between two different types of encapsulants. However, the difference between the encapsulants is that they have a different viscoelasticity in cured condition, resulting in reduced mechanical stress as temperature changes. This application publication does not mention the need or advantage of a low change of dimensions during curing.

In an embodiment, the first encapsulant material, which is e.g. the material of the backside encapsulant, is a material comprising at least a first layer and a second layer. The first layer is preferably made of a dimensionally stable material. Dimensionally stable means that the “change of dimensions” is relatively low.

The second layer is made of or comprises a polymer material, which softens and/or melts at a temperature above room temperature (room temperature being 20° C.). In this embodiment, the second layer of the first encapsulant material is for example attached to the backside of the solar cells. When heating the first side encapsulant, optionally the second layer of the first encapsulant material gets tacky at a sticking temperature, and the solar cells are attached to the first side encapsulant when the second layer of the first encapsulant material is at the sticking temperature.

Optionally the first layer has a melting temperature which is above a curing temperature of the second layer and/or of the second encapsulant material of the second side encapsulant.

Optionally, the first encapsulant material comprises a third layer, which is provided on the first layer, on the side of the first layer opposite to the side where the second layer is present.

Optionally, the first encapsulant material is a foil or film. Optionally, the first layer forms a core of the foil or film and the second layer forms an outer skin of the foil or film.

The first layer of the first encapsulant material provides dimensional stability to the first side encapsulant (e.g. backside encapsulant) during heating of the first side encapsulant in a laminator.

In an embodiment the first side encapsulant (e.g. the backside encapsulant (BSE)) has a sticking temperature at which the first side encapsulant (e.g. the backside encapsulant (BSE)) gets tacky and the second side encapsulant (e.g. the frontside encapsulant (FSE)) has a curing temperature at which the second side encapsulant (e.g. the frontside encapsulant (FSE)) cures, the backside encapsulant (BSE) is heated to the sticking temperature at which the solar cells attach to the first side encapsulant (e.g. the backside encapsulant (BSE)) before the second side encapsulant (e.g. the frontside encapsulant (FSE)) is heated to the curing temperature at which the solar cells attach to second side encapsulant (e.g. the frontside encapsulant (FSE)), as a result of which the cells attach to the first side encapsulant (e.g. the backside encapsulant (BSE)) before attaching to the second side encapsulant (e.g. the frontside encapsulant (FSE)).

In this embodiment the solar cells stick to the first side encapsulant (e.g. the backside encapsulant (BSE)) as the sticking temperature where the first side encapsulant (e.g. the backside encapsulant (BSE)) becomes tacky is a lower temperature than the temperature where the second side encapsulant (e.g. the frontside encapsulant (FSE)) cures.

In another embodiment before curing the FSE a first stack comprising the backside encapsulant (BSE) and the solar cells is heated/cured, the first stack not comprising the frontside encapsulant (FSE), thereby attaching the solar cells to the backside encapsulant (BSE), and then the frontside encapsulant (FSE) is added to the first stack, resulting in a second stack comprising the first stack and the FSE, after which the second stack is cured.

By dividing the method in two stages, a first stage in which the solar cells are attached to the backside encapsulant (BSE) and a second stage in which the first stack formed in the first stage is supplemented with a frontside encapsulant (FSE), the solar cells can be adhered to the backside encapsulant (BSE) before being attached to the frontside encapsulant (FSE). This makes the process flexible by first raising the temperature to a temperature where the backside encapsulant (BSE) gets tacky, and optionally curing the backside encapsulant (BSE), and after thus fixing the cells to the backside encapsulant (BSE) add the frontside encapsulant (FSE) to the first stack and cure the frontside encapsulant (FSE).

In a further embodiment the first stack further comprises a removable protective sheet removably attached to the frontside of the solar cells, the removable sheet removed before the frontside encapsulant (FSE) is added to the first stack.

The removable sheet protects the solar cells from contamination and mechanical damage until the removable sheet is removed just prior to adding the frontside encapsulant (FSE) to the first stack. This makes handling of the first stack, such as taking it out of the laminator etc., less risky.

In another embodiment before curing the second stack a transparent single or double curved cover is added to the second stack such that the frontside encapsulant (FSE) is between the cover and the solar cells.

This transparent cover is for example a glass or polycarbonate plate, facing the environment. Preferably it should offer a stable geometry, protect the solar cells from impact of objects such as hail, and limit the amount of UV penetrating into the stacks attached to it. As an alternative the second stack is attached to the transparent cover at a later stage.

It is noted that typically the cover and the stack are adhered to each other in a so-called bag laminator, in which a workpiece is inserted in a bag, the bag is evacuated, and then the (outside of the bag is heated to a curing temperature.

In yet another embodiment after curing the stack, incisions are made in at least part of the stack to increase the flexibility of the cured stack.

Typically the cured stack comprising the encapsulants and optionally the back-contact foil form a stiff wafer due to the curing and cross-linking. If it is to be bonded to a curved surface, incisions can be made to increase flexibility, as described in e.g. Dutch patent application NL2027572 or US patent application publication US20140130848A1.

In still another embodiment the backside of the solar cells comprises both anodes and cathodes, and a back contact foil (BCF) electrically interconnecting solar cells.

Preferably the back-contact foil (BCF) is placed against the backside encapsulant (BSE) opposite to the solar cells. The back-contact foil (BCF) has a patterned metallic, preferably copper, cladding. Dots of conductive glue or solder can be applied between the solar cells and the back-contact foil (BCF), although also laser welding is known to be used.

In yet another embodiment the stack is placed on a carrier, the stack comprising a first anti-stick layer closest to the carrier, a back contact foil (BCF) in contact with the first anti-stick layer, a backside encapsulant (BSE) in contact with the back-contact foil (BCF), solar cells in contact with the backside encapsulant (BSE), a frontside encapsulant (FSE) in contact with the solar cells, and a second anti-stack layer in contact with the frontside encapsulant (FSE), after which the stack is placed on a carrier and in the laminator in such an orientation that the frontside encapsulant (FSE) is further removed from the laminators' heater than the backside encapsulant (BSE), the laminator is evacuated, the membrane of the laminator is made to press on the second anti-stick layer of the stack, and the temperature of the carrier is ramped in such a time and to such a temperature, that the solar cells stick and/or attach to the backside encapsulant (BSE) before the frontside encapsulant (FSE) starts to cure, after which the carrier is kept at a temperature at which the frontside encapsulant (FSE) completely cures, and finally the heating of the carrier is stopped and the evacuated laminator is vented so that the carrier with the stack can be removed.

The carrier, typically a flat plate such as a glass plate, an aluminium plate or such, is heated in the laminator. Anti-stick layers are used to avoid the backside encapsulant (BSE) and the frontside encapsulant (FSE) sticking to the parts of the laminator. Also, as they are anti-stick, they can thus be simply removed from the encapsulants. The temperature is raised sufficiently quickly for the backside encapsulant (BSE) to attach (stick) to the solar cells before the solar cells attach (stick) to the frontside encapsulant (FSE).

In still another embodiment a first stack is placed on a carrier, the first stack comprising a first anti-stick layer closest to the carrier, optionally a release film in contact with the first anti-stick layer, solar cells in contact with the release film or the anti-stick layer, a rear encapsulant in contact with the solar cells, back contact foil in contact with the rear encapsulant and a second anti-stick layer in contact with the back contact foil, after which the carrier is in a laminator brought to a temperature at which the solar cells stick to the rear encapsulant, the heating of the carrier is stopped and the evacuated laminator is vented so that the carrier with the first stack can be removed and in a later stage the stack is formed by removing the optional release film and adding the frontside encapsulant film and the stack is heated in a laminator to a temperature at which the frontside encapsulant cures.

If solder paste is applied to the solar cells and/or the back-contact foil (BCF) before connecting (soldering, gluing) the solar cells to the back-contact foil (BCF) the solder paste can be cured as well, typically at a temperature of 80° C. After this first heating cycle the heating of the carrier is stopped and the evacuated laminator is vented so that the carrier with the first stack can be removed. In a later stage the stack is formed by removing the optional release film and adding the frontside encapsulant film and the stack is heated in a laminator to a temperature at which the frontside encapsulant (FSE) cured.

It is noted that during the second heating cycle one or more anti-stick layers can be used.

In a further embodiment the stack is placed on a single or double curved transparent cover with the surface in contact with the frontside encapsulant (FSE).

This second step can be performed on the curved cover of the final product, such as a glass curved panel or a polycarbonate curved panel. This second step can be performed in a standard laminator, or in a bag laminator. A bag laminator is a big bag in which the workpiece (stack) is placed, the bag is evacuated and then the bag is heated to curing temperature.

Also during the second heating cycle anti-stick layers can be used.

In another embodiment the backside encapsulant (BSE) comprises a polymer, polyester or a plastic film.

Inventors found that foils comprising a polymer, a polyester or a plastic core, and a cladding of for example EVA (ethylene vinyl acetate) show a low change of dimensions.

In yet another embodiment the carrier is a glass plate.

Laminators, including pin laminators, often use a glass plate as a carrier plate. This glass carrier plate should not be confused with the transparent cover, that may be a glass plate as well.

In still another embodiment between the carrier and the heater of the laminator a breather cloth is placed.

By placing a breather cloth between the laminators' heater and the carrier the evacuable volume of the laminator can be evacuated quickly and only when the pressure in the volume is low, thermal contact between the heater and the glass plate occurs, thus starting the heating of the glass and thus the stack placed on the carrier. This eliminates the need for a so-called pin laminator, that uses mechanical pins to change the distance between the heater and the carrier, lowering the carrier to the heater when heating should start. The solution using a breather cloth is a “poor man's” solution well suited for low volume production.

In yet another embodiment the frontside encapsulant is an encapsulant from the group of EVA, POE, PVB, ionomer, PDMS, TPU, TPO, PU and silicone.

These materials are known to be used as encapsulants for solar modules.

In still another embodiment the solar cells show anodes and cathodes at the backside, the stack comprises a back-contact foil (BCF) for electrically interconnecting the solar cells, the backside encapsulant (BSE) equipped with holes aligned with the anodes and the cathodes at the backside of the solar cells, between the back-contact foil (BCF) and the solar cells a conductive material at least partly filling the holes, the conductive material cured while heating the stack.

The method further pertains to a solar panel, comprising:
solar cells, the solar cells (104) having a photosensitive frontside (106) sensitive to light and a backside (108)
a first side encapsulant (114), which first side encapsulant is made of a first encapsulant material, the first side encapsulant being attached to one of photosensitive frontside (106) or the backside of the solar cells,
a second side encapsulant (112) being attached to the other one of the photosensitive frontside (106) or the backside of the solar cells, the second side encapsulant (114) being made of a second encapsulant material which is different from the first encapsulant material, and
wherein the first encapsulant material has a change of dimensions which is less than the change of dimensions of the second encapsulant material.

Optionally, in the solar panel according to the invention, the first side encapsulant is a backside encapsulant and the second side encapsulant is a frontside encapsulant. Alternatively, the first side encapsulant is a frontside encapsulant and the second side encapsulant is a backside encapsulant.

Optionally, the method according to the invention is used to manufacture the solar panel according to the invention.

In an embodiment, the first encapsulant material, which is e.g. the material of the backside encapsulant, is a material comprising at least a first layer and a second layer. The first layer is preferably made of a dimensionally stable material. Dimensionally stable means that the “change of dimensions” is relatively low.

The second layer is made of or comprises a polymer material, which softens and/or melts at a temperature above room temperature (room temperature being 20° C.). In this embodiment, the second layer of the first encapsulant material is for example attached to the backside of the solar cells. When heating the first side encapsulant, optionally the second layer of the first encapsulant material gets tacky at a sticking temperature, and the solar cells are attached to the first side encapsulant when the second layer of the first encapsulant material is at the sticking temperature.

Optionally the first layer has a melting temperature which is above a curing temperature of the second layer and/or of the second encapsulant material of the second side encapsulant.

Optionally, the first encapsulant material comprises a third layer, which is provided on the first layer, on the side of the first layer opposite to the side where the second layer is present.

Optionally, the first encapsulant material is a foil or film. Optionally, the first layer forms a core of the foil or film and the second layer forms an outer skin of the foil or film.

The first layer of the first encapsulant material provides dimensional stability to the first side encapsulant (e.g. backside encapsulant) during heating of the first side encapsulant in a laminator.

The invention further pertains to a method in accordance with any one of the following clauses:
1. Method for laminating solar cells using a laminator,
the laminator having an evacuable volume for placing a workpiece therein, the volume comprising a heatable plate for heating the workpiece, the volume showing a membrane for pressing against the workpiece when the volume is evacuated,
the solar cells (104) having a photosensitive frontside (106) sensitive to light and a backside (108),
the method comprising attaching a backside encapsulant (114) to the backside of the solar cells and attaching a frontside encapsulant (112) to the frontside of the solar cells, the frontside encapsulant showing a high transmissivity for light, the encapsulants and the solar cells forming at least part of a stack,
characterized in that
the backside encapsulant (114) shows in uncured condition a change of dimensions less than the change of dimensions of the frontside encapsulant (112) in uncured condition and the solar cells (104) are attached to the backside encapsulant before the solar cells are attached to the frontside encapsulant, as a result of which drifting of the solar cells before being attached to the frontside encapsulant is decreased.
2. The method of clause 1 in which the backside encapsulant (114) has a sticking temperature at which the backside encapsulant gets tacky and the frontside encapsulant (112) has a curing temperature at which the frontside encapsulant cures, the backside encapsulant is heated to the sticking temperature at which the solar cells attach to the backside encapsulant (114) before the frontside encapsulant is heated to the curing temperature at which the solar cells (104) attach to the frontside encapsulant, as a result of which the solar cells attach to the backside encapsulant (114) before attaching to the frontside encapsulant (112).
3. The method of clause 1 or clause 2 in which before curing the frontside encapsulant (112) a first stack comprising the backside encapsulant (114) and the solar cells (104) is heated/cured, the first stack not comprising the frontside encapsulant (112), thereby attaching the solar cells to the backside encapsulant, and then the frontside encapsulant is added to the first stack, resulting in a second stack comprising the first stack and the frontside encapsulant, after which the second stack is cured.
4. The method of clause 3 in which the first stack further comprises a removable protective sheet removably attached to the frontside (106) of the solar cells (104), the removable sheet removed before the frontside encapsulant (112) is added to the first stack.
5. The method of clause 3 in which before curing the second stack a transparent single or double curved cover (102) is added to the second stack such that the frontside encapsulant (112) is between said cover and the solar cells (104).
6. The method of any of the preceding clauses in which after curing of the stack incisions are made in at least part of the stack to increase the flexibility of the cured stack.
7. The method of any of the preceding clauses in which the backside (108) of the solar cells (104) comprises both anodes and cathodes, and a back contact foil (118) electrically interconnecting solar cells (104).
8. The method of clause 1 or clause 2 in which the stack is placed on a carrier, the stack comprising a first anti-stick layer closest to the carrier, a back contact foil in contact with the first anti-stick layer, a backside encapsulant in contact with the back contact foil, solar cells in contact with the backside encapsulant, a frontside encapsulant in contact with the solar cells, and a second anti-stick layer in contact with the frontside encapsulant, after which the stack is placed on a carrier and in the laminator in such an orientation that the frontside encapsulant is further removed from the laminators' heater than the backside encapsulant, the laminator is evacuated, the membrane of the laminator is made to press on the second anti-stick layer of the stack, and the temperature of the carrier is ramped in such a time and to such a temperature, that the solar cells stick and/or attach to the backside encapsulant before the frontside encapsulant starts to cure, after which the carrier is kept at a temperature and during a time at which the frontside encapsulant completely cures, and finally the heating of the carrier is stopped and the evacuated laminator is vented so that the carrier with the stack can be removed and the anti-stick layers can be removed.
9. The method of clause 1 or clause 2 in which a first stack is placed on a carrier, the first stack comprising a first anti-stick layer closest to the carrier, optionally a release film in contact with the first anti-stick layer, solar cells in contact with the release film or the anti-stick layer, a backside encapsulant in contact with the solar cells, back contact foil in contact with the backside encapsulant and a second anti-stick layer in contact with the back contact foil, after which the carrier is in a laminator brought to a temperature at which the solar cells stick to the backside encapsulant, the heating of the carrier is stopped and the evacuated laminator is vented so that the carrier with the first stack can be removed and in a later stage the stack is formed by removing the optional release film and adding the frontside encapsulant film and the stack is heated in a laminator to a temperature at which the frontside encapsulant cures.
10. The method of clause 9 in which the stack is placed on a single or double curved transparent cover with the surface in contact with the frontside encapsulant
11. The method of any of the preceding clauses in which the backside encapsulant comprises a polymer, a polyester or a plastic film with a low change of dimensions.
12. The method of any of the preceding clauses in which the carrier is a glass plate.
13. The method of any of the preceding clauses in which between the carrier and the heater of the laminator a breather cloth is placed.
14. The method of any of the preceding clauses in which the front side encapsulant is an encapsulant from the group of EVA, POE, PVB, Ionomer, PDMS, TPU, Silicone, TPO, and PU.
15. The method of any of the clauses 7-9 in which the solar cells show anodes and cathodes at the backside, the stack comprises a back contact foil for electrically interconnecting the solar cells, the backside encapsulant equipped with holes aligned with the anodes and cathodes at the backside of the solar cells, between the back contact foil and the solar cells a conductive material at least partly filling the holes, the conductive material cured while heating the stack.

### BRIEF DESCRIPTION OF THE DRAWINGS

The invention is now elucidated using figures, in which identical reference signs indicate corresponding features. To that end:

FIG. 1 schematically shows a cross section of a solar panel,

FIG. 2 schematically shows a prior art flowchart for producing the solar panel of figure

FIG. 3 schematically shows a flowchart for producing a solar panel according to the invention, and

FIG. 4 schematically shows a method where the backside encapsulant (BSE) is heated before the frontside encapsulant (FSE) is heated.

### DETAILED DESCRIPTION OF THE INVENTION

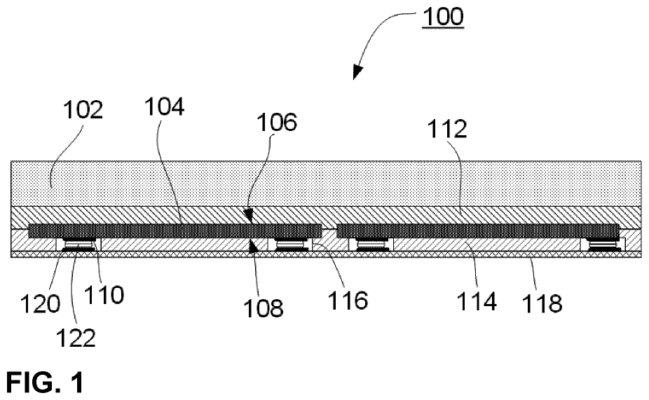

FIG. 1 schematically shows a cross section of a solar panel.

A solar panel 100 comprises a transparent cover 102, such as a glass plate or a polycarbonate plate. The plate may be flat, as often the case in domestic solar panels, or it can be a 3D curved cover, as used, for example, when using the solar panel as a panel of a solar vehicle, such as the Lightyear One, sold by Atlas Technologies B.V., Helmond, the Netherlands. The transparent cover protects the rest of the solar panel from the environment. The solar panel further comprises solar cells 104 having a photosensitive side 106 and a backside 108, the backside equipped with electrodes 110 (cathodes and anodes). As the cover 102 is a transparent cover, sunlight can irradiate the photosensitive side of the solar cells. The solar cells are encapsulated in a transparent frontside encapsulant (FSE) 112 and a backside encapsulant (BSE) 114. Typically the two encapsulants are from an identical material, such as EVA, although it is known to use different types of encapsulants. Via holes 116 in the backside encapsulant (BSE) electrical contact is made between the electrodes (anodes, cathodes) of the solar cells with a metallisation pattern 120 on a back-contact foil (BCF) 118. In that respect the back-contact foil (BCF) resembles a flexible printed circuit board. Between the metallisation pattern 120 and the electrodes 110 a dot of a conductive glue or solder 122 is applied making an electrical connection between the solar cells and the back-contact foil (BCF), thereby enabling serialization and/or parallelization of the solar cells, as well as connectivity to electronic modules. The frontside encapsulant (FSE), the solar cells, the backside encapsulant (BSE) and the back-contact foil (BCF) are laminated in a laminator, preferably a pin laminator, in which the layers of frontside encapsulant (FSE) 112 and backside encapsulant (BSE) encapsulant 114 are bonded together and bonded to the solar cells. This happens under vacuum or at least a much reduced pressure and at a temperature of typically between 120-150° C., at which temperature curing (cross-linking) of the encapsulants occurs.

At the beginning of the lamination process the position of the solar cells is not yet fixed. At an elevated temperature the encapsulant becomes tacky, but due to the thickness of the sheets of encapsulant the cells tend to drift a bit before the encapsulant is sufficiently cured to fix the position. Also the encapsulants suffer from a change in dimensions, often anisotropic, thereby displacing the solar cells. These effects may lead to the cells touching each other, leading to shorts between the solar cells, or a displacement that is not esthetic.

It is noted that a glass of fiberglass underpinning, or other laminates comprising for example glass fiber, carbon fiber or such like, may be mounted on the solar panel opposite to the side that is sensitive to light, to offer extra strength to the stack.

It is further noted that when the solar panel uses an interconnection method using small metal wires between the cells, the method known as “tabbing” and the wires as “finger electrodes”, displacement of the solar cells is unlikely to occur due to the rigid position governed by the finger electrodes. For flat solar panels as used for housing this tabbing is done automatically, but for curved panel this is only feasible when the cells are arranged in strips and the distance between the strips is varied, leading to a loss of area where solar light is converted to electricity, see also US patent application publication US20140130848A1.

The problem is thus especially relevant for technology using back contact foil (backsheet technology) where the cells are interconnected in two dimensions by a for example copper cladded back-contact foil (BCF).

It is noted that often a slab of frontside encapsulant (FSE), solar cells, backside encapsulant (BSE) and back-contact foil (BCF) is bonded to the transparent cover by adding an extra sheet of EVA between the slab and the transparent plate, and then cure the extra sheet in a pin laminator.

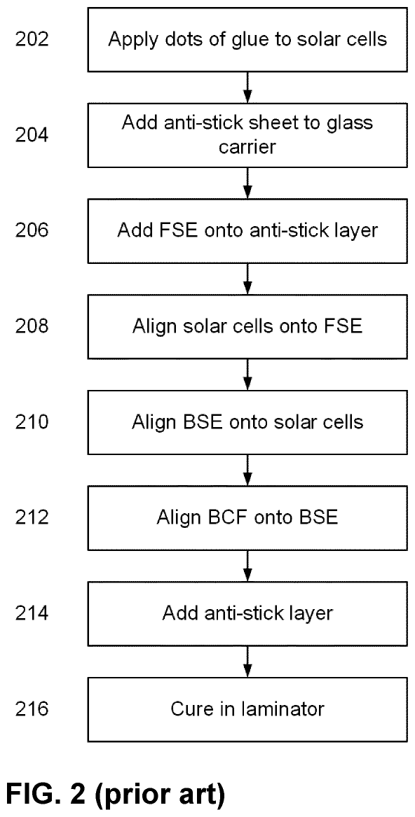

FIG. 2 schematically shows a prior art flowchart for producing the solar panel of FIG. 1.

It is noted that the phrase “layer” and “sheet” are used interchangeably.

In a first step 202 a dot of conductive glue is applied to each electrode (anode, cathode) of each solar cell.

In a second step 204 an anti-stick layer of for example ETFE is placed on a glass carrier. This anti-stick layer makes it easier to separate the carrier from subsequent placed sheets after lamination.

In a third step 206 a first sheet of a transparent encapsulant, such as EVA is placed on the anti-stick layer. This is the frontside encapsulant (FSE).

In a fourth step 208 the solar cells are placed and aligned on the frontside encapsulant (FSE). The photosensitive side contacts the frontside encapsulant (FSE).

In a fifth step 210 a second sheet of an encapsulant, such as EVA, is placed on the solar cells. This is the backside encapsulant (BSE). The backside encapsulant (BSE) shows holes, and the holes are aligned with the electrodes and the dots of conductive glue are placed thereon.

In a sixth step 212 a back contact foil (BCF) is placed on the backside encapsulant (BSE).

In a seventh step 214 the thus formed stack is covered with an extra anti-stick layer to avoid the stack attaching to the membrane of the laminator when the stack is placed in a laminator.

In an eighth step 216 this stack is cured in a laminator, such as a pin laminator.

Many variants of this method can be chosen, in which the main stack formed in steps 202-214 are produced by forming several stacks. As an example: the dots of conductive glue can be added to the solar cells and the back contact foil can be aligned with the cells in a still later step. The glass carrier can be a metal carrier, such as an aluminium plate.

The method is finished by placing the main stack in the transparent cover (a glass plate or a polycarbonate plate, curved or flat) of the final product, together with one or more sheets of frontside encapsulant (FSE) and cured. This curing is typically carried out in a so-called bag laminator, in which the main stack, the transparent cover and the extra layers of frontside encapsulant (FSE) are placed in a bag, the bag is evacuated, and the bag is heated to a curing temperature.

It is noted that other variants form the main stack upside down, and thus place the back-contact foil (BCF) near the heater and the first layer of encapsulant near the membrane of the laminator.

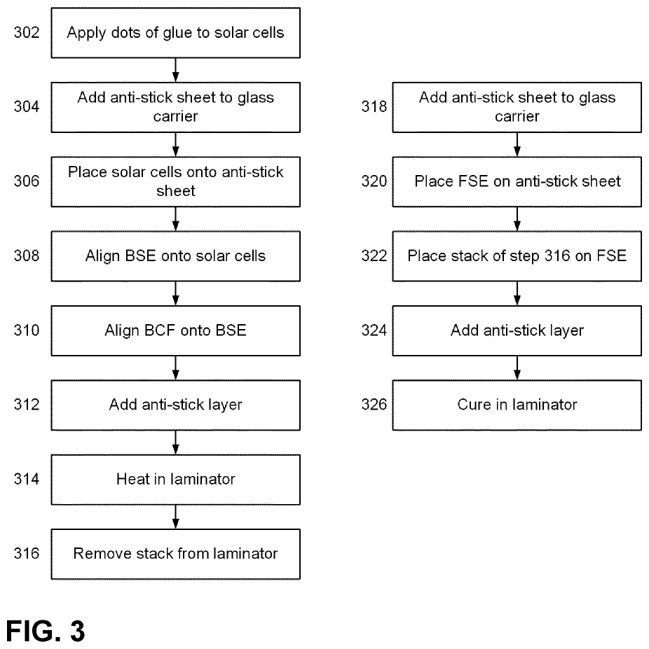

FIG. 3 schematically shows a first method for producing a solar panel according to the invention.

When laminating solar cells, often cell drifting occurs: as the dimensions of the uncured laminates, such as EVA, change during the lamination process due thermal expansion, shrinkage due to cross-linking, dimensional change due to relaxation of strain, etc. the solar cells (104) tend to drift before the cells attach (‘tack’) to the encapsulant. The invention describes methods to avoid this drifting by first adhering the cells to a backside encapsulant (114) with a low dimensional change, such as an encapsulant with a polyester or plastic core. An example of such a laminate is EPE. This backside encapsulant need not be transparent. After the cells attach to the backside encapsulant the cells are adhered to a frontside encapsulant (112) that is highly transparent, such as EVA, and cured.

For this method there is provided conductive glue, a laminator, a glass carrier, sheets of anti-stick material, a sheet of backside encapsulant (BSE), a sheet of frontside encapsulant (FSE) and solar cells.

In a first step 302 dots of conductive glue are applied to the solar cells or the back-contact foil (BCF).

In a second step 304 an anti-stick layer of for example ETFE is placed on the glass carrier.

In a third step 306 the solar cells are positioned on the anti-stick film with their photosensitive side on the anti-stick film.

In a fourth 308 step the backside encapsulant (BSE) sheet with a low change in dimensions showing holes is placed upon and aligned with the solar cells such that the electrodes (with conductive glue) align with the holes.

In a fifth step 310 the back-contact foil (BCF) is placed upon and aligned with the backside encapsulant (BSE). The cells, the backside encapsulant (BSE) and the back-contact foil (BCF) are aligned such that the electrodes of the cells make after curing of the conductive paste electrical contact with the metallisation of the back-contact foil (BCF) via the conductive dots.

It is noted that the dimensional change of the back-contact foil (BCF) is negligible compared to that of the frontside encapsulant (FSE).

In a sixth step 312 a second anti-stick sheet is placed on the back-contact foil (BCF).

In a seventh step 314 the glass carrier with the stack formed thereon is placed in the laminator and the stack is cured or at least heated to such a temperature that the solar cells stick to the backside encapsulant (BSE).

It is noted that the BS backside encapsulant (BSE) encapsulant is e.g. EPE and shows a change in dimensions of less than 0.5% as compared to a change in dimensions of between 4 and 6% for a normal EVA sheet.

It is further noted that the curing of the (encapsulant of the) EPE need not be complete. Assuming the EPE comprises two thin layers of EVA, as applicable to the EPE film of 3M™ company (see -1-), at a temperature of approximately 80° C. the EVA layer(s) gets tacky and, even after cooling down, the cells stay attached to the film (the cells stay fixed/adhered), and thus the cells stay positioned with respect to each other.

In an eighth step 316 the stack is removed from the laminator.

In a ninth step 318 an anti-stick layer is placed on the glass carrier,

In the tenth step 320 the frontside encapsulant (FSE) sheet is placed on the anti-stick layer,

In an eleventh step 322 the stack formed in step 314 is placed on the anti-stick layer with the cells placed on the frontside encapsulant (FSE),

In a twelfth step 324 an anti-stick layer is placed on the stack.

In a thirteenth step 326 this stack is cured in the laminator. The outcome of this step 326 is equivalent with that of step 216. Although more steps are needed, it is noted that the intermediate heating at step 314 takes little time compared to the final step 326.

It is noted that the anti-stick film applied in step 304 can be kept in contact with the solar cells until the sheet formed in step 314 is placed on the frontside encapsulant (FSE) in step 322.

It is further noted that the anti-stick film can be supplemented with a so-called release film, acting as a protective film after step 314. The release film protects the solar cells during processing and is removed just prior to bringing the cells in contact with the front encapsulant in step 322. The release film is an easily removable film, for example a film of FEP, POE, HDPE, PP, PE, PMP, Fluoropolymer, or PTFE. The release film protects the solar cells and the back-side encapsulant along the whole process until it is removed, thus eliminating the need for cleaning the cells. The release film can be an anti-stick film that is not removed directly after step 316

The important difference between the prior art method and the method according to the invention is that the backside encapsulant (BSE)—for example EPE (EVA/Polymer/EVA)—shows a dimensional change (shrinkage) of less than 0.5% as compared to a 4 to 6% dimensional change (shrinkage) for a normal EVA sheet, that is used as a frontside encapsulant (FSE). This enables placing the cells at a distance of, for example, 1% of their dimensions from each other without the risk of the cells touching each other and thereby getting electrically shorted.

Experiments show that this so-called cell drift in the cured product is reduced from 6 mm per 850 mm (0.8%) to less than 1 mm per 850 mm (appr. 0.1%) when using EVA as frontside encapsulant (FSE) and EPE as backside encapsulant (BSE).

It is noted that many variants on this method can be thought of. For example: the conductive glue can be applied to the solar cells, or to the back-contact foil (BCF). The back-contact foil (BCF) with the dots of glue can be added in a later stage, for example when curing the stack to the transparent plate. The laminator can heat the workpiece using infra-red heaters. The laminator can be a pin laminator, or the glass carrier can be placed on a breather cloth that brings the glass carrier into contact with the heater(s) when the evacuable volume is evacuated. All these and other variants are part of the invention. The BSE and/or BCF foil can be white, black or another color, depending on esthetic or other considerations.

It is noted that the flowchart shown in FIG. 2 also results in the method according to the invention, provided that the backside encapsulant (BSE) that is used in step 210 is of a material that shows low change of dimensions and sticks to the cells before the frontside encapsulant (FSE) sticks to the cells. By using for instance EPE as a backside encapsulant (BSE) and EVA as a frontside encapsulant (FSE), and controlling heating temperature in time this can be achieved.

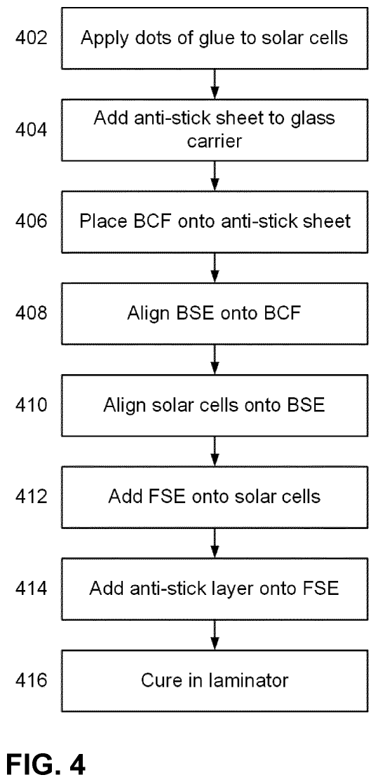

FIG. 4 schematically shows a method where the backside encapsulant (BSE) is heated before the frontside encapsulant (FSE) is heated.

For this method there is provided conductive glue, a laminator, a glass carrier, sheets of anti-stick material, a sheet of backside encapsulant (BSE), a sheet of frontside encapsulant (FSE) and solar cells.

In a first step 402 a dispenser dispenses dots of conductive glue the solar cells or the back-contact foil (BCF). Also another method, such as a printing method may be used.

In a second step 404 an anti-stick layer of for example ETFE is placed on a glass carrier.

In a third step 406 the back-contact foil (BCF) is placed on the anti-stick layer.

In a fourth step 408 the backside encapsulant (BSE) with holes is aligned on the back-contact foil (BCF),

In a fifth step 410 the solar cells are aligned to the backside encapsulant (BSE),

In a sixth step 412 a sheet of frontside encapsulant (FSE), such as EVA, is placed on the solar cells,

In a seventh step 414 anti-stick sheet is placed on the frontside encapsulant (FSE),

In an eighth step 416 the thus formed stack is cured in a laminator.

As here the backside encapsulant (BSE) is closer to the (heated) glass carrier than the frontside encapsulant (FSE), the interface between BSE and solar cells will be heated before the interface between frontside encapsulant (FSE) and solar cells get hot. Therefore, with appropriate materials (for example EPE as a backside encapsulant (BSE) and EVA as frontside encapsulant (FSE) and appropriate temperature control, the cells will stick to the backside encapsulant (BSE) before cell drift due to the frontside encapsulant (FSE) will occur.

### REFERENCES

[-1-] 3M™ EPE film: https://multimedia.3m.com/mws/media/752595O/3m-epe-films-application-quide.pdf

1. A method for laminating solar cells,
which method comprises the following steps:
attaching a first side encapsulant to solar cells, which first side encapsulant is made of a first encapsulant material,
the solar cells having a photosensitive frontside sensitive to light and a backside, and the first side encapsulant being attached to one of the photosensitive side and the backside of the solar cells,
forming at least a part of a stack by, after attaching the first side encapsulant to the solar cells, attaching a second side encapsulant to the other one of the photosensitive side and the backside of the solar cells, the second side encapsulant being made of a second encapsulant material which is different from the first encapsulant material, and wherein the first encapsulant material has a change of dimensions which is less than the change of dimensions of the second encapsulant material.

2. The method according to claim 1,
wherein the first side encapsulant is a backside encapsulant, and the second side encapsulant is a frontside encapsulant having a transmissivity for light, and
wherein in the step of the attaching the solar cells to the first side encapsulant, the backside of the solar cells is attached to the backside encapsulant, and
wherein the in the step of forming at least a part of a stack, the frontside encapsulant is attached to the photosensitive side of the solar cells.

3. The method according to claim 1,
in which method a laminator is used which has an evacuable volume for placing a workpiece therein, the volume comprising a heatable plate for heating the workpiece, and the volume showing a membrane for pressing against the workpiece when the volume is evacuated.

4. The method of claim 1,
wherein the backside encapsulant is heated to a sticking temperature at which the backside encapsulant gets tacky, and wherein the solar cells are attached to the backside encapsulant when the backside encapsulant is at the sticking temperature, and
wherein after heating the backside encapsulant to the sticking temperature, the frontside encapsulant is heated to a curing temperature and wherein the solar cells are attached to the frontside encapsulant when the frontside encapsulant is at the curing temperature.

5. The method of claim 1,
wherein the solar cells are attached to the backside encapsulant to form a first stack, and wherein the frontside encapsulant is added to the first stack to form a second stack, the first stack therewith becoming part of the second stack,
wherein the method further comprises the following steps:
before attaching the frontside encapsulant to the solar cells of the first stack, curing the first stack,
after forming the second stack by adding the frontside encapsulant to first stack, curing the second stack.

6. The method of claim 5,
in which a removable protective sheet removably is provided on the frontside of the solar cells,
wherein the method further comprises the step of removing the removable sheet before the frontside encapsulant is added to the first stack.

7. The method of claim 5,
wherein the method further comprises the step of:
before curing the second stack, adding a transparent single or double curved cover to the second stack and arranging the single or double sided cover such that the frontside encapsulant is between said single or double cover and the solar cells.

8. The method of claim 1,
wherein after curing of the stack, incisions are made in at least part of the stack.

9. The method of claim 1,
wherein solar cells are used wherein both the anodes and the cathodes are arranged on the backside of the solar cells,
and wherein the method further comprises the step of:
arranging a back contact foil a side of the backside encapsulant facing away from the solar cells, and electrically interconnecting solar cells via the back contact foil.

10. The method of claim 1,
which method further comprises the following steps:
placing on a carrier, a stack comprising:
a first anti-stick layer, the first ant-stick layer being closest to the carrier,
a back contact foil, in contact with the first anti-stick layer
a backside encapsulant, in contact with the back contact foil,
solar cells, the backside of the solar cells being in contact with the backside encapsulant,
a frontside encapsulant, in contact with the frontside of the solar cells, and
a second anti-stick layer, in contact with the frontside encapsulant,
arranging the carrier with the stack thereon in the laminator, with the frontside encapsulant being further removed from the laminators' heater than the backside encapsulant,
evacuating the laminator,
making the membrane of the laminator press on the second anti-stick layer of the stack,
increasing the temperature of the carrier in such a time and to such a temperature, that the solar cells become attached to the backside encapsulant before the frontside encapsulant starts to cure,
keeping the carrier at a temperature during a time which allows the frontside encapsulant cures to the desired level,
stopping heating of the carrier, venting the laminator and removing the carrier from the laminator,
removing the anti-stick layers from the stack.

11. The method of claim 1,
which method comprises the following steps:
placing on a carrier, a first stack comprising:
a first anti-stick layer, which first ant-stick layer is closest to the carrier,
optionally a release film in contact with the first anti-stick layer,
solar cells in contact with the release film or the anti-stick layer,
a backside encapsulant in contact with the solar cells,
back contact foil in contact with the backside encapsulant, and
a second anti-stick layer in contact with the back contact foil,
after placing the first stack on the carrier, in a laminator bringing the carrier to a temperature at which the solar cells stick to the backside encapsulant,
stopping the heating of the carrier, evacuating the laminator and venting the evacuated laminator so that the carrier with the first stack can be removed, and,
in a later stage, forming the stack by:
if applicable, removing the optional release film, and
adding the frontside encapsulant film, and
heating the stack in a laminator to a temperature at which the frontside encapsulant cures.

12. The method of claim 11 in which the stack is placed on a single or double curved transparent cover with the surface in contact with the frontside encapsulant.

13. The method of claim 1 in which the backside encapsulant that is used is or comprises a dimensionally stable polymer, a polyester or a plastic film, and/or
in which the front side encapsulant is an encapsulant from the group of EVA, POE, PVB, Ionomer, PDMS, TPU, Silicone, TPO, and PU.

14. The method of claim 1 in which the carrier which is used is a glass plate, and/or
in which between the carrier and the heater of the laminator a breather cloth is placed.

15. The method of claim 9 in which the solar cells which are used have anodes and cathodes at the backside, the stack comprises a back contact foil for electrically interconnecting the solar cells, the backside encapsulant equipped with holes aligned with the anodes and cathodes at the backside of the solar cells, between the back contact foil and the solar cells a conductive material at least partly filling the holes,
and wherein the conductive material is cured while heating the stack.

16. The method according to claim 1,
wherein a first encapsulant material is used which comprises a first layer and a second layer, wherein the second layer is made of or comprises a polymer material, which softens and/or melts at a temperature above 20° C.,
wherein the second layer of the backside encapsulant is attached to the backside of the solar cells, and
wherein the second layer gets tacky at a sticking temperature when heating the backside encapsulant, and the solar cells are attached to the backside encapsulant when the second layer of the backside encapsulant is as the sticking temperature.

17. A solar panel, comprising:
solar cells, the solar cells having a photosensitive frontside sensitive to light and a backside,
a first side encapsulant, which first side encapsulant is made of a first encapsulant material, the first side encapsulant being attached to one of photosensitive frontside or the backside of the solar cells,
a second side encapsulant being attached to the other one of the photosensitive frontside or the backside of the solar cells, the second side encapsulant being made of a second encapsulant material which is different from the first encapsulant material, and
wherein the first encapsulant material has a change of dimensions which is less than the change of dimensions of the second encapsulant material.
